(19) United States
(12) Patent Application Publication
(10) Pub. No.: US 2006/0090692 A1
(43) Pub. Date: May 4, 2006

(54) Generating nano-particles for chemical mechanical planarization

(76) Inventors: Juan E. Dominguez, Hillsboro, OR (US); Kyle Y. Flanigan, Portland, OR (US); Baohua Niu, Portland, OR (US); Ernisse Putna, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/976,593

(22) Filed: Oct. 29, 2004

(51) Int. Cl. C30B 15/14; C30B 25/00; C30B 28/12; C30B 28/14; C30B 23/00

(52) U.S. Cl. 117/101; 117/937; 117/3

(57) ABSTRACT

An embodiment of the present invention is a technique to generate particles for use in a slurry solution for chemical mechanical planarization (CMP). Reverse micelles are formed using at least one of an oxide and a metal in a mixture. The size of the reverse micelles is tuned to a desired size. The particles are formed inside the reverse micelles. The particles are precipitated and transferred to a slurry solution.

### BACKGROUND

1. Field of the Invention

Embodiments of the invention relate to the field of semiconductors, and more specifically, to semiconductor fabrication processes.

2. Description of Related Art

Chemical mechanical polishing or planarization (CMP) is widely used in various industrial applications ranging from optical lens polishing to storage media and semiconductor manufacturing. It is a common process to planarize semiconductor wafers. The CMP combines chemical action with mechanical abrasion to achieve selective material removal through polishing. CMP is a very complex process with a total number of variables sometimes exceeding 20. Some important variables include the size distribution and properties of the abrasive particles. The size and distribution of particles can modulate processes such as removal rate, zeta potential, chemical potential conditions for uniform particle solution, removal sensitivity and shelf life. Future material CMP requirements including soft low k interlayer dielectrics necessitate advances in particle size and distribution control to increase material removal and avoid collapse.

Existing techniques for controlling the size and distribution of particles have a number of disadvantages. In one technique, the size of the particles may be controlled by adjusting the reaction time, temperature, and the ethyl silicate concentration using the hydrolysis reaction. Another technique uses post fabrication filtering to select desired particle sizes. These techniques, however, result in a relatively wide particle distribution leading to batch-to-batch variations. In addition, these techniques are not flexible in controlling sizes and size distribution of the particles. They also require complex and expensive equipment.

### BRIEF DESCRIPTION OF THE DRAWINGS

The embodiments of invention may best be understood by referring to the following description and accompanying drawings that are used to illustrate embodiments of the invention. In the drawings:

FIG. 1 is a diagram illustrating a system in which one embodiment of the invention can be practiced.

FIG. 2 is a diagram illustrating a process to fabricate the nano-particles using reverse micelles according to one embodiment of the invention.

FIG. 3 is a diagram illustrating a process to fabricate the nano-particles using dendrimers according to one embodiment of the invention.

FIG. 4 is a flowchart illustrating a process to fabricate the nano-particles using reverse micelles according to one embodiment of the invention.

FIG. 5 is a flowchart illustrating a process to fabricate the nano-particles using reverse micelles with surfactant near critical micelle concentration (CMC) according to one embodiment of the invention.

FIG. 6 is a flowchart illustrating a process to fabricate the nano-particles using dendrimers with branching reactant according to one embodiment of the invention.

FIG. 7 is a flowchart illustrating a process to fabricate the nano-particles using dendrimers with reverse micelles according to one embodiment of the invention.

### DESCRIPTION

An embodiment of the present invention is a technique to generate particles for use in a slurry solution for chemical mechanical planarization (CMP). Reverse micelles are formed using at least one of an oxide and a metal in a mixture. The size of the reverse micelles is tuned to a desired size. The particles are formed inside the reverse micelles. The particles are precipitated and transferred to a slurry solution

In the following description, numerous specific details are set forth. However, it is understood that embodiments of the invention may be practiced without these specific details. In other instances, well-known circuits, structures, and techniques have not been shown to avoid obscuring the understanding of this description.

One embodiment of the invention may be described as a process which is usually depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a program, a procedure, a method of manufacturing or fabrication, etc.

Embodiments of the invention provide nano-particles used in a slurry solution for CMP applications. Some advantages of embodiments of the invention include: (1) uniform size distribution of slurry abrasive particles, (2) flexibility in controlling particle sizes, and (3) stabilization and useful shelf life of resulting slurry solutions.

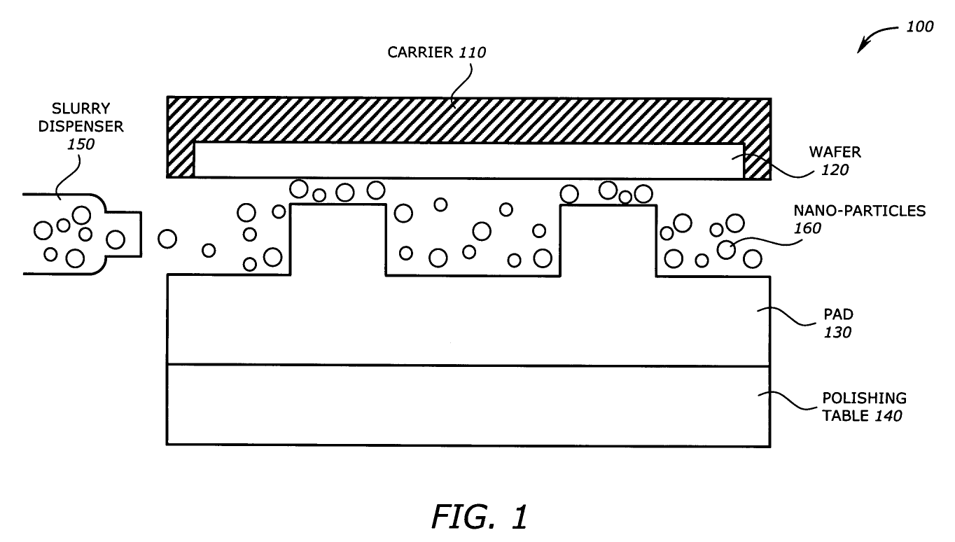

FIG. 1 is a diagram illustrating a system 100 in which one embodiment of the invention can be practiced. The system 100 includes a carrier 110, a wafer 120, a pad 130, a polishing table 140, and a slurry dispenser 150.

The carrier 110 holds the wafer 120 during the chemical mechanical planarization or polishing (CMP) process. The carrier 110 may have a rotational movement with respect to the polishing table 140. The wafer 120 is a semiconductor wafer that needs to be polished or planarized. Typically, the wafer 120 is held by the carrier 110 upside down.

The pad 130 is used to provide a polishing structure to polish or planarize the wafer 120. It is placed and secured on top of the polishing table 140. The polishing table 140 may have a rotational and translational movement with respect to the carrier 110. Typically, the polishing table 140 and the carrier 110 have movements that are independently controlled.

The slurry dispenser 150 holds a slurry solution. The slurry solution has a large number of nano-particles 160. The slurry dispenser 150 dispenses or injects the slurry solution to the area between the wafer 120 and the pad 130. The nano-particles 160 are fabricated using an embodiment of the invention. The nano-particles 160 are spread across the surfaces of the pad 130 and the wafer 120 by the rotational or translational movement of the pad 130 or the carrier 110. The nano-particles 160 are preferably metal oxides such as ceria, silica, alumina, titania, zirconia, germania, hematite, magnesia, yttria, tin oxide, or a polymer. The nano-particles 160 have uniform sizes. The average particle size may range from 10 to 50 nanometers. It is, however, contemplated that particles having sizes less than 10 nanometers or greater than 50 nanometers may also be used.

The particles 160 in the slurry solution may be fabricated, constructed, or made using embodiments of the invention. One embodiment uses the reverse micelles. Micelle stabilization is used to create uniformly sized particles. This method utilizes surfactant molecules having opposite charges at the hydrophobic and hydrofilic ends. After the critical micelle concentration (CMC) is approached and surfaces are covered with the corresponding molecule, the surfactant molecules agglomerate into spherical clusters. These clusters are formed in such a way to minimize the surface energy, resulting in solvent-repulsive ends facing the center of the sphere. The nanometer-sized water spheres trapped inside these micelles act as nano-reactors for molecule formation. The material to be produced inside the micelles may be delivered in form of a soluble salt (e.g., nitrate or sulfate) with the addition of reducing or oxidating agents to create the intended material. Another embodiment uses dendrimer growth. Dendrimer growth may be used to control the size and the size distribution of the particles. One interesting topological aspect of dendrimers is the concept of the starburst limit. Typically, the number of branch ends on a dendrimer increases exponentially as a function of generation, while the surface area of the dendrimer only increases with the square of generation. Particles may be formed inside the dendrimer with controllable growth. The particles may be precipitated using heat, irradiation, or introduction of a soluble reactant (e.g., isopropyl alcohol) inside the micelle.

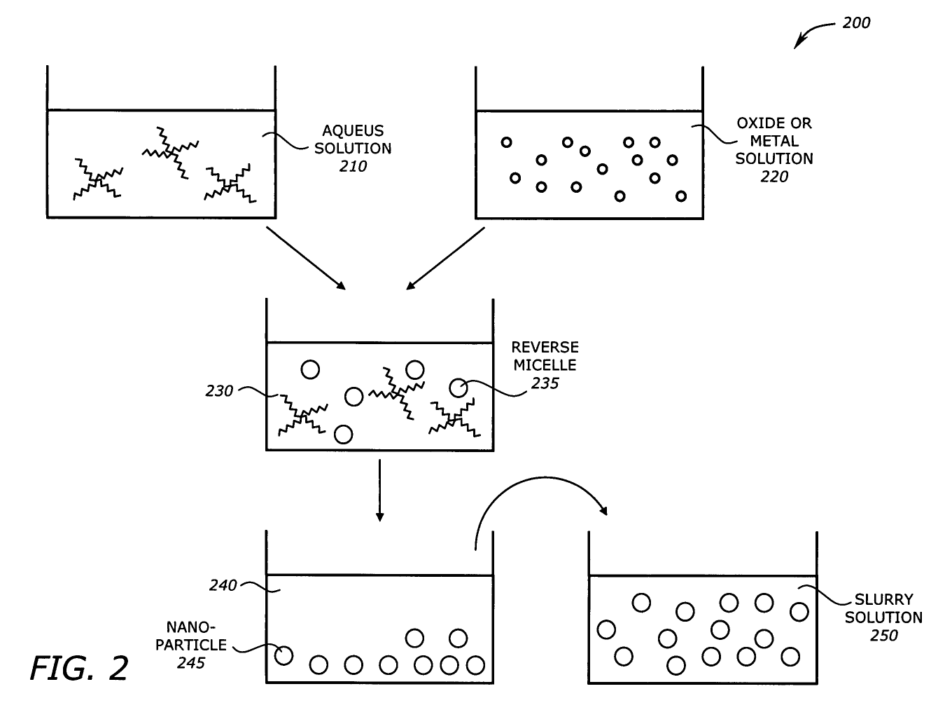

FIG. 2 is a diagram illustrating a process 200 to fabricate the nano-particles using reverse micelles according to one embodiment of the invention.

The process 200 starts with two solutions 210 and 220. The solution 210 is an aqueous solution with a surfactant and an agent. The solution 210 may include a micro-emulsion. The emulsion includes a continuous phase and a disperse phase. The disperse phase is the isolated phase stabilized by the surfactant. The solution 220 is a solution having a material for the particles. It may be one of an oxide and a metal. It may be one of a silicon oxide (SiO₂), aluminum oxide (Al₂O₃), cerium oxide (CeO₂), zirconium oxide (ZrO₂), calcium carbonate (CaCO₃), barium oxide, nickel oxide, manganese oxide, cobalt oxide, and copper (Cu). In one embodiment, a number of oxide materials may be combined to obtain the desired properties.

The two solutions are mixed to provide the mixture 230. The mixing may be accompanied by rapid stirring with a specified time period (e.g., 15 minutes). The mixture 230 contains reverse micelles 235 which are formed to encapsulate the particles inside. The size of the reverse micelles can be controlled, adjusted, or tuned using a number of mechanisms such as controlling the reaction time, adjusting the surfactant concentration, and controlling the pH of the mixture. Typically, a decrease in the surfactant concentration leads to an increase in average and maximum particle sizes.

The particles 245 in the reverse micelles 235 are then separated or precipitated into material 240. The material 240 is then transferred to a solution to become a slurry solution 250 used for the CMP process.

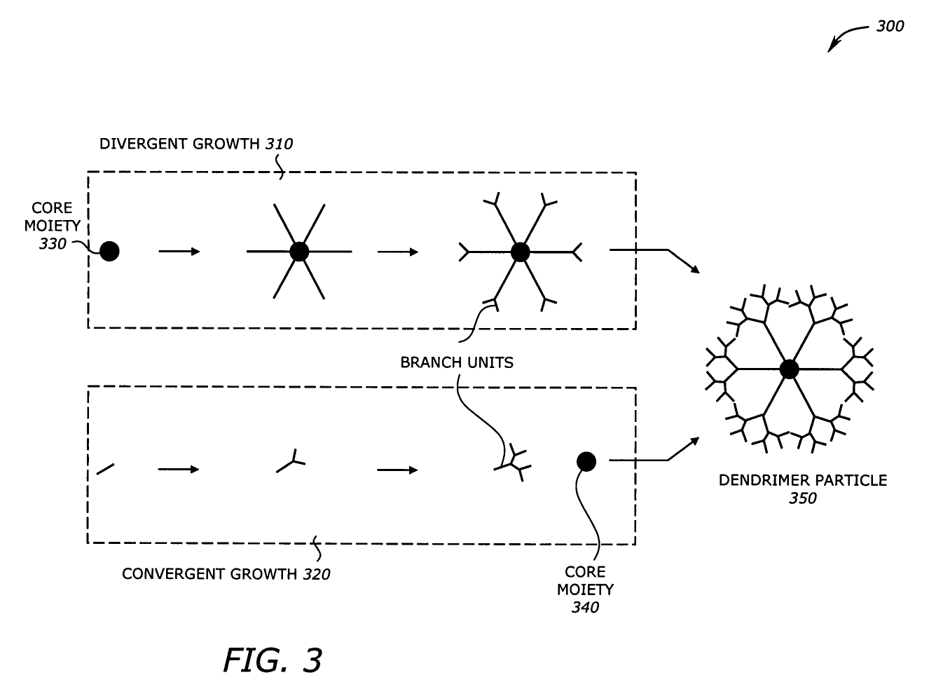

FIG. 3 is a diagram illustrating a process 300 to fabricate the nano-particles using dendrimers according to one embodiment of the invention. The process 300 includes a divergent growth 310 and a convergent growth 320. Both of the divergent and convergent growths 310 and 320 result in dendrimer particle 350 which is used in a slurry solution for the CMP process.

The divergent growth starts with a seed particle made of one of an oxide and metal as the core moiety 330. A generation of branches is grown starting from this core moiety 320. The size of the dendrimer particle 350 may be controlled by adding appropriate branching reactant or using reverse micelles.

The convergent growth starts with the final surface of the dendrimer particle 350 and works inward by gradually linking the surface units together with more monomers. At the end, a core moiety 340 is attached to form the complete dendrimer particle 350.

In addition to these growths, dendrimer particles may also be formed using other techniques such as double exponential and exact positioning of building blocks. These techniques provide flexible ways to control the size and distribution of the resulting particles.

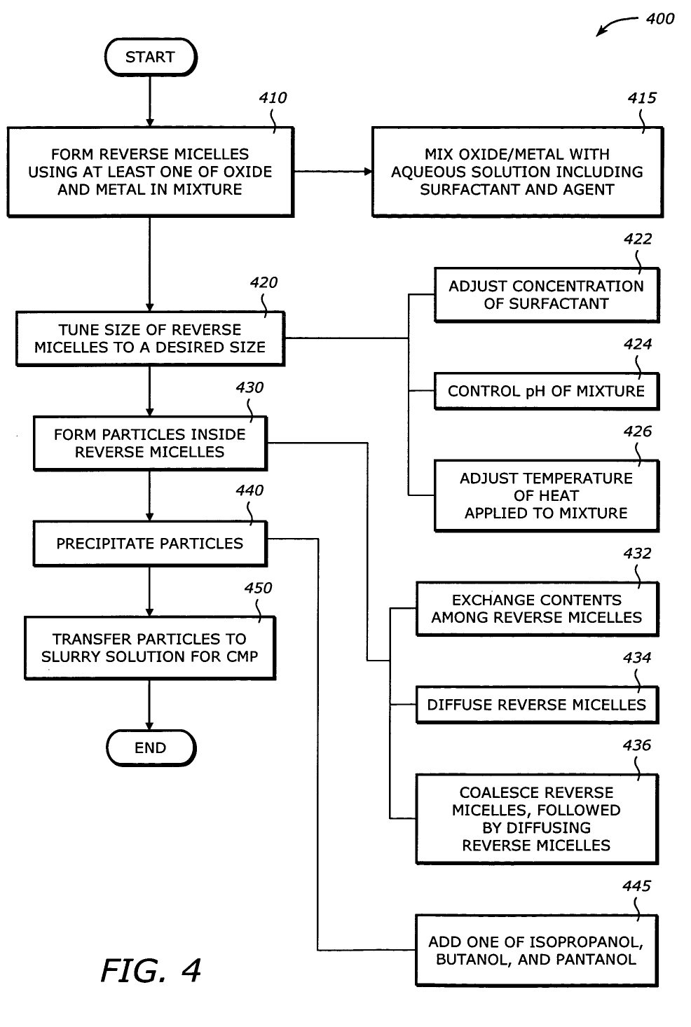

FIG. 4 is a flowchart illustrating a process 400 to fabricate the nano-particles using reverse micelles according to one embodiment of the invention.

Upon START, the process 400 forms reverse micelles using at least one of an oxide and metal in a mixture or an aqueous composition (Block 410). This can be accomplished by mixing the oxide or metal with an aqueous solution which includes a surfactant and an agent (Block 415). The surfactant may be one of an anionic surfactant, a nonionic surfactant, a zwitterionic surfactant, an amphoteric surfactant, and any combination of these surfactants. The surfactant is used to stabilize the resulting reverse micelles. The surfactant may be one of a sodium dodecylsulfate (SDS), a sodium deoxycholate, a diisooctyl sodium sulphosuccinate (commonly referred to as aerosol OT or AOT), polyethoxylated alcohols, polyethoxylated phenols, oleates, phospholipids, sorbitan ester, poloxamer, polyoxyethylene sorbitan ester, polyoxyethylene ester, and any mixture of these. The agent may be a reducing agent or a reactant such as iso-octane.

Next, the process 400 tunes the size of the reverse micelles to a desired size (Block 420). The desired size may be a range of sizes. The size of the reverse micelles is proportional to the resulting particles. The size here refers to the diameter of the reverse micelles or the particles. The size of the reverse micelles may be controlled using a number of methods. One method is to adjust the concentration of the surfactant (Block 422). Another method is to control the pH level of the mixture by adding an acid or base agent in a suitable amount to the mixture (Block 424). Acidic agents to lower the pH of the mixture may include sulfuric acid, perchloric acid, hydrochloric acid, phosphoric acid, and nitric acid. Basic agents to raise the pH of the mixture may include potassium hydroxide, sodium hydroxide, and ammonium hydroxide. Yet, another technique is to adjust the temperature of the heat applied to the mixture (Block 426).

Next, the process 400 forms particles inside the reverse micelles (Block 430). This can be accomplished by a number of methods. One method is to exchange the contents among the reverse micelles (Block 432). Another method is to diffuse the reverse micelles (Block 434). Yet another method is to coalesce the reverse micelles and then diffuses the reverse micelles (Block 436).

Then, the process 400 precipitates the particles (Block 440). This can be accomplished by adding a precursor to the mixture. The precursor may be one of an iso-propanol, a butanol, and a pentanol. The precursor breaks down the reverse micelles so that the particles can be isolated. Next, the process 400 transfers the particles to a slurry solution for use in a CMP process (Block 450) and is then terminated.

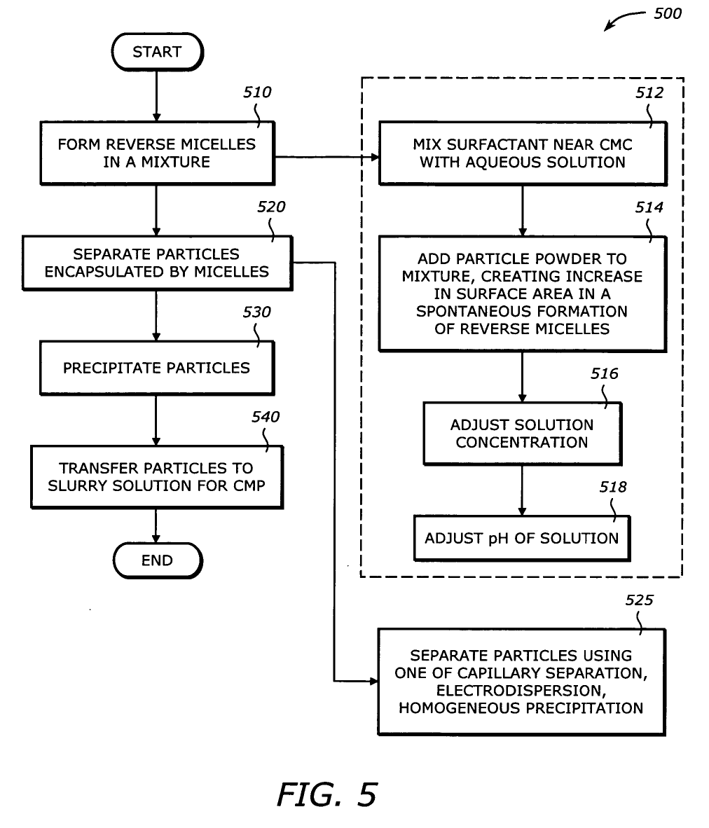

FIG. 5 is a flowchart illustrating a process 500 to fabricate the nano-particles using reverse micelles with surfactant near critical micelle concentration (CMC) according to one embodiment of the invention.

Upon START, the process 500 forms reverse micelles in a mixture (Block 510). This can be accomplished by a number of operations. First, the process performed by Block 510 mixes a surfactant near a critical micelle concentration (CMC) with an aqueous solution (Block 512). The CMC depends on the type of surfactant. Typical ranges are from 10⁻⁴ to 10⁻⁶ mMol/L. Then, the process 500 adds particle powders to the mixture (Block 514). The particle powders create an increase in the surface area in a spontaneous formation of the reverse micelles. Next, the process 500 adjusts the solution concentration (Block 516). This can be done by selecting a specified amount of the surfactant with respect to the aqueous solution. Then, the process 510 adjusts the pH level of the solution (Block 518) as described above.

Next, the process 500 separates the particles encapsulated by the reverse micelles (Block 520). This can be performed by separating the particles using one of a capillary separation, an electro-dispersion, or a homogeneous precipitation (Block 525). Next, the process 500 transfers the particles to a slurry solution for used in a CMP process (Block 540) and is then terminated.

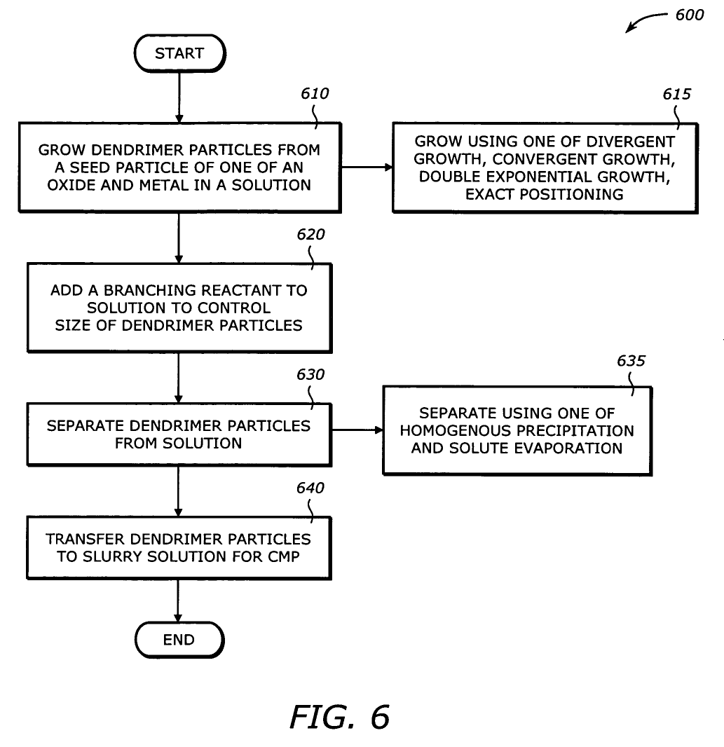

FIG. 6 is a flowchart illustrating a process to fabricate the nano-particles using dendrimers with branching reactant according to one embodiment of the invention.

Upon START, the process 600 grows dendrimer particles from a seed particle of one of an oxide and metal in a solution (Block 610). This can be accomplished by growing the dendrimer particles using one of a divergent growth, a convergent growth, a double exponential growth, and an exact positioning with building blocks (Block 615). Next, the process 600 adds a branching reactant to the solution to control the size of the dendrimer particles (Block 620). An example of the branching reactant is isopropyl alcohol. The size of the dendrimer particles may also be controlled by stopping the growth at a specified generation number.

Then, the process separates the dendrimer particles from the solution (Block 630). This can be accomplished by using one of a homogeneous precipitation and a solute evaporation (Block 635). Heat may be applied to enhance reactions. Irradiation (e.g., ultraviolet) may also be used to enhance reactivity to certain compounds. Next, the process 600 transfers the dendrimer particles to a slurry solution for a CMP process (Block 640) and is then terminated.

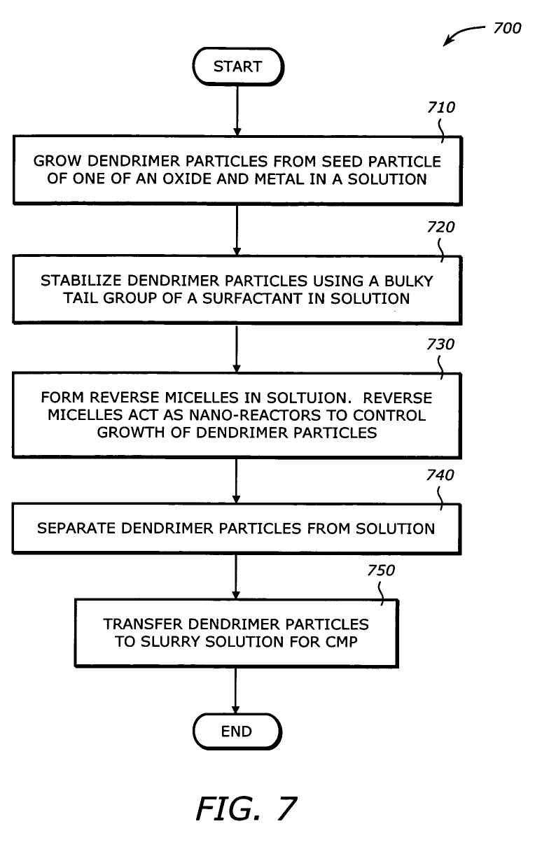

FIG. 7 is a flowchart illustrating a process 700 to fabricate the nano-particles using dendrimers with reverse micelles according to one embodiment of the invention.

Upon START, the process 700 grows dendrimer particles from a seed particle of one of an oxide and a metal in a solution (Block 710). Next, the process 700 stabilizes the dendrimer particles using a bulky tail group of a surfactant in the solution (Block 720).

Then, the process 700 forms reverse micelles in the solution (Block 730). The reverse micelles act as nano-reactors to control the growth of the dendrimer particles (Block 730). This growth control allows tuning the size of the dendrimer particles to a desired size. Next, the process 700 separates the dendrimer particles from the solution (Block 740). This can be accomplished by using one of a homogeneous precipitation and a solute evaporation as in Block 635 in FIG. 6. Next, the process 600 transfers the dendrimer particles to a slurry solution for a CMP process (Block 750) and is then terminated.

While the invention has been described in terms of several embodiments, those of ordinary skill in the art will recognize that the invention is not limited to the embodiments described, but can be practiced with modification and alteration within the spirit and scope of the appended claims. The description is thus to be regarded as illustrative instead of limiting.

What is claimed is:

1. A method comprising:
forming reverse micelles using at least one of an oxide and a metal in a mixture;
tuning size of the reverse micelles to a desired size;
forming particles inside the reverse micelles;
precipitating the particles; and
transferring the particles to a slurry solution.

2. The method of claim 1 wherein forming reverse micelles comprises:
mixing the at least one of an oxide and a metal with an aqueous solution including a surfactant and an agent to form the mixture.

3. The method of claim 1 wherein the at least one of an oxide and a metal is one of a silicon oxide (SiO₂), aluminum oxide (Al₂O₃), cerium oxide (CeO₂), zirconium oxide (ZrO₂), calcium carbonate (CaCO₃), barium oxide, nickel oxide, manganese oxide, cobalt oxide, and copper (Cu).

4. The method of claim 1 wherein tuning comprises at least one of:
adjusting concentration of the surfactant;
controlling a pH of the mixture by adding an acid or a base in a suitable amount; and
adjusting temperature of heat applied to the mixture.

5. The method of claim 1 wherein forming the particles comprises one of:
exchanging contents among the reverse micelles;
coalescing the reverse micelles; and
diffusing among the reverse micelles.

6. The method of claim 1 wherein precipitating comprises:
adding a precursor to the mixture.

7. The method of claim 6 wherein adding the precursor comprises:
adding one of a isopropanol, a butanol, and a pentanol precursor.

8. The method of claim 2 wherein the surfactant is at least one of an anionic surfactant, a nonionic surfactant, a zwitterionic surfactant, and an amphoteric surfactant.

9. A method comprising:
forming reverse micelles in a mixture;
separating particles encapsulated by the micelles;
precipitating the particles; and
transferring the particles to a slurry solution.

10. The method of claim 9 wherein forming the reverse micelles comprises:
mixing a surfactant near a critical micelle concentration (CMC) with an aqueous solution to form the mixture; and
adding particle powders to the mixture, the particle powders creating an increase in surface area resulting in a spontaneous formation of the reverse micelles.

11. The method of claim 10 wherein forming the reverse micelles further comprises:
adjusting solution concentration of the mixture; and
adjusting pH of the mixture.

12. The method of claim 9 wherein separating the particles comprises:
separating the particles using one of a capillary separation, an electro-dispersion, and a homogeneous precipitation.

13. A method comprising:
growing dendrimer particles from a seed particle of one of an oxide and metal in a solution;
adding a branching reactant to the solution to control size of the dendrimer particles;
separating the dendrimer particles from the solution; and
transferring the dendrimer particles to a slurry solution for chemical mechanical planarization (CMP).

14. The method of claim 13 wherein growing the dendrimer particles comprises:
growing the dendrimer particles using one of a divergent growth, a convergent growth, a double exponential growth, and an exact positioning of building blocks.

15. The method of claim 13 wherein separating the dendrimer particles comprises:
separating the dendrimer particles from the solution using one of a homogeneous precipitation and a solute evaporation.

16. A method comprising:
growing dendrimer particles from a seed particle of one of an oxide and metal in a solution;
forming reverse micelles in the solution, the reverse micelles acting as nanoreactors to control growth of the dendrimer particles;
separating the dendrimer particles from the solution; and
transferring the dendrimer particles to a slurry for chemical mechanical planarization (CMP).

17. The method of claim 16 further comprising:
stabilizing the dendrimer particles using a bulky tail group of a surfactant in the solution.

18. The method of claim 16 wherein separating the dendrimer particles comprises:
separating the dendrimer particles from the solution using one of a homogeneous precipitation and a solute evaporation.

19. A mixture comprising:
a plurality of reverse micelles formed from at least one of an oxide and metal and an aqueous solution including a surfactant and an agent; and
a plurality of particles formed inside the reverse micelles, the plurality of particles to be precipitated and transferred to a slurry solution used in a chemical mechanical planarization (CMP) process.

20. The mixture of claim 19 wherein the reverse micelles have sizes controlled by at least one of a surfactant concentration, a pH level of the mixture, and a temperature of heat applied to the mixture.

21. The mixture of claim 19 wherein the surfactant is one of an anionic surfactant, a nonionic surfactant, a zwitterionic surfactant, and an amphoteric surfactant.

22. The mixture of claim 19 further comprising:
one of a isopropanol, a butanol, and a pentanol precursors to precipitate the plurality of particles.

23. A mixture comprising:
a plurality of dendrimer particles formed from a seed particle of one of an oxide and metal in a solution; and
a branching reactant to control size of the dendrimer particles.

24. The mixture of claim 23 wherein the dendrimer particles are grown using one of a divergent growth, a convergent growth, a double exponential growth, and an exact positioning of building blocks.

25. The mixture of claim 24 wherein the dendrimer particles are separated from the solution using one of a homogeneous precipitation and a solute evaporation.

26. A mixture comprising:
a plurality of dendrimer particles formed from a seed particle of one of an oxide and metal in a solution; and
a plurality of reverse micelles acting as nanoreactors to control growth of the dendrimer particles.

27. The mixture of claim 26 wherein the dendrimer particles are grown using one of a divergent growth, a convergent growth, a double exponential growth, and an exact positioning of building blocks.

28. The mixture of claim 26 wherein the dendrimer particles are separated from the solution using one of a homogeneous precipitation and a solute evaporation.
